(19) United States
(12) Patent Application Publication
(10) Pub. No.: US 2024/0181654 A1
(43) Pub. Date: Jun. 6, 2024

(54) PAD AND END EFFECTOR

(71) Applicant: Tokyo Electron Limited, Tokyo (JP)

(72) Inventors: Hideyuki OSADA, Miyagi (JP); Koya HASHIMOTO, Miyagi (JP)

(73) Assignee: Tokyo Electron Limited, Tokyo (JP)

(21) Appl. No.: 18/530,360

(22) Filed: Dec. 6, 2023

Related U.S. Application Data
(60) Provisional application No. 63/430,398, filed on Dec. 6, 2022.

(30) Foreign Application Priority Data
Aug. 3, 2023 (JP) 2023-127027

(51) Int. Cl. B25J 15/00; B25J 11/00

(52) U.S. Cl. CPC B25J 15/0014; B25J 11/0095; B25J 15/0019

(57) ABSTRACT

A pad for an end effector of a substrate transfer device is provided. The pad includes a base portion and a main portion. The main portion is in continuity with the base portion in a first direction. The main portion includes a lower surface, a first end, a second end, and an upper surface. The first end is one end of the main portion in a second direction perpendicular to the first direction. The second end is the other end of the main portion in the second direction. A distance between a reference surface including the lower surface and the upper surface increases from the first end to the second end. The upper surface has a maximum height at the second end with respect to the reference surface. The main portion has elasticity. The main portion forms a space below the second end.

### CROSS-REFERENCE TO RELATED APPLICATIONS

This application claims priority to U.S. Patent Application No. 63/430,398, filed on Dec. 6, 2022, and Japanese Patent Application No. 2023-127027, filed on Aug. 3, 2023, the entire contents of each are incorporated herein by reference.

### TECHNICAL FIELD

Exemplary embodiments of the present disclosure relate to a pad and an end effector.

### BACKGROUND

A transfer device used to transfer a substrate includes a transfer robot. A substrate transfer device described in Japanese Laid-open Patent Publication No. 2017-208451 has a pad on the upper surface of a hand so as to prevent the substrate from slipping on the hand of the transfer robot.

### SUMMARY

The present disclosure provides a technology for suppressing the positional misalignment of a substrate on an end effector.

In an exemplary embodiment, a pad for an end effector of a substrate transfer device is provided. The pad comprises a base portion and a main portion. The main portion is in continuity with the base portion in a first direction. The main portion comprises a lower surface, a first end, a second end and an upper surface. The lower surface is extending from the base portion in a direction intersecting the first direction. The first end is one end of the main portion in a second direction perpendicular to the first direction. The second end is the other end of the main portion in the second direction. The second end terminates the main portion and the pad in the second direction. A distance between a reference surface including the lower surface and the upper surface increases from the first end to the second end. The upper surface has a maximum height at the second end with respect to the reference surface. The main portion has elasticity. The main portion forms a space below the second end.

### BRIEF DESCRIPTION OF THE DRAWINGS

FIG. 1 is a block diagram of a computer-based system that functions as a controller for controlling a transfer arm according to the present disclosure.

FIG. 2 is a plan view of an end effector according to an exemplary embodiment.

FIG. 3 is a perspective view of a pad according to an exemplary embodiment.

FIG. 4 is a side view of the pad according to an exemplary embodiment.

FIGS. 5A and 5B are partially enlarged sectional views of the end effector according to an exemplary embodiment.

FIG. 6A is a sectional view of a pad according to another exemplary embodiment, and FIG. 6B is a sectional view of a pad according to a further exemplary embodiment.

### DETAILED DESCRIPTION

Hereinafter, various exemplary embodiments will be described.

In an exemplary embodiment, a pad for an end effector of a substrate transfer device is provided. The pad includes a base portion and a main portion. The main portion is in continuity with the base portion in a first direction. The main portion includes a lower surface, a first end, a second end, and an upper surface. The lower surface extends from the base portion in a direction intersecting the first direction. The first end is one end of the main portion in a second direction perpendicular to the first direction. The second end is the other end of the main portion in the second direction. The second end terminates the main portion and the pad in the second direction. A distance between a reference surface including the lower surface and the upper surface increases from the first end to the second end. The upper surface has a maximum height at the second end with respect to the reference surface. The main portion has elasticity. The main portion forms a space below the second end.

Further, according to an aspect of the present disclosure, a novel substrate mounting (holding) pad for a transfer arm and a substrate processing device using the substrate mounting pad are disclosed.

According to an exemplary embodiment of the present disclosure, a mounting pad and an end effector having the mounting pad are provided. The mounting pad is a mounting pad for mounting an object, and includes a base portion and a mounting portion provided on one side of the base portion. The mounting portion has a slope having a predetermined angle with respect to the surface direction of one side of the base portion, and the slope is located on a side opposite to the one side and also includes a holding portion protruding from the one side in a plan view.

According to an exemplary embodiment, since the mounting portion has the slope and the holding portion for holding an object above the slope, the holding portion may hold the object even if the object is warped or bent. A contact area between the holding portion and the object or a holding force for the object varies depending on the weight of the object.

According to an exemplary embodiment, when the mounting pad is placed on the end effector such as a transfer pick, the mounting pad is disposed on a circumference, and the holding portion is arranged to be farthest from the center of the circumference, so that it is possible to apply a drag force to the object in an inner direction of the circumference, thereby preventing the object from sliding outward. In addition, it is more difficult to attach and easier to separate the pad as compared to a conventional mounting pad.

According to an exemplary embodiment of the present disclosure, by adjusting the thickness of the holding portion, changing the shape of the holding portion, or adjusting the area of the holding portion, it is possible to further improve the flexibility and durability of the holding portion.

In this specification, the singular forms are intended to include the plural forms as well, unless the context clearly indicates otherwise. Furthermore, reference to “an embodiment” of the present disclosure is not intended to be interpreted as excluding the presence of additional embodiments having the recited features.

A control method and a control system described herein may be implemented using computer programming or computer engineering techniques including computer software, firmware, hardware, or combinations or subsets thereof. The technical effect may at least include processing a substrate in a plasma processing apparatus using a transfer arm having a pad according to the present disclosure.

Hereinafter, various exemplary embodiments will be described in detail with reference to the accompanying drawings. In addition, the same reference numerals are given to the same or similar parts throughout drawings.

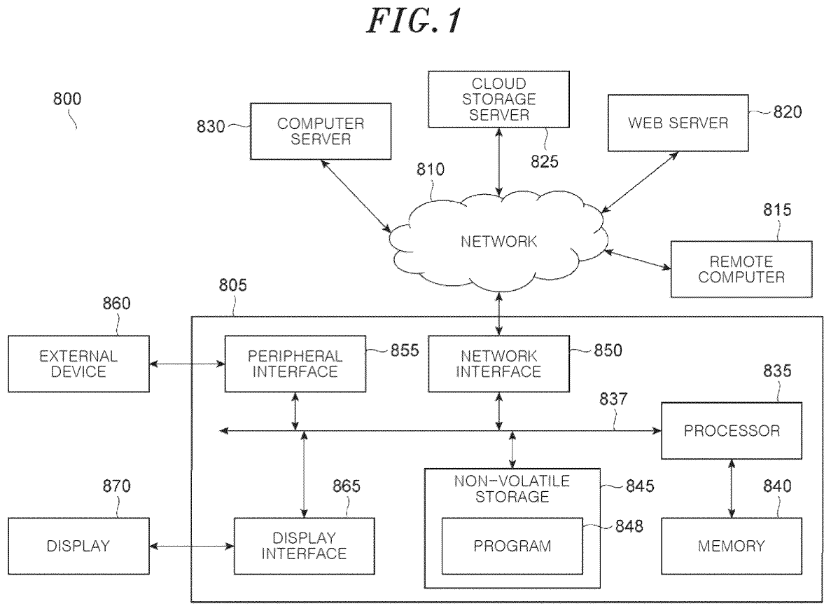

FIG. 1 is a block diagram of a computer-based system that functions as a controller for controlling a transfer arm according to an embodiment of the present disclosure.

The control aspect of the present disclosure may be implemented as a system, method, and/or computer program product. The computer program product may include a computer-readable recording medium. A computer-readable program instruction for executing an aspect of an embodiment on one or more processors is recorded on the recording medium.

The computer-readable recording medium may be a type of device that may store an instruction used by an instruction execution device (processor). The computer-readable storage medium may be, for example, an electronic storage device, a magnetic storage device, an optical storage device, an electromagnetic storage device, a semiconductor storage device, or any suitable combination of these devices, but are not limited thereto. A non-exhaustive list of more specific examples of the computer-readable storage medium includes a flexible disk, a hard disk, a solid state drivee (SSD), a random access memory (RAM), a read-only memory (ROM), an erasable programmable read-only memory (EPROM or flash), a static random access memory (SRAM), a compact disk (CD or CD-ROM), a digital versatile disk (DVD), and a memory card or a stick (and appropriate combinations thereof). In the present disclosure, the computer-readable storage medium itself should not be interpreted as a transitory signal, such as a radio wave or other free-propagating electromagnetic waves, an electromagnetic wave (e.g., a pulse of light passing through a fiber optic cable) propagating in a waveguide or other transmission media, or an electrical signal transmitted over an electrical wire.

The computer-readable program instruction described in the present disclosure may be transmitted from the computer-readable storage medium to a proper computer device or processing device, or be downloaded in an external computer or an external storage device via a global network (Internet), a local area network, a wide area network, and/or a wireless network. The network may include a copper transmission line, an optical communication fiber, a wireless transmission, a router, a firewall, a switch, a gateway computer, and/or an edge server. A network adapter card or network interface of the computer device or processing device may receive the computer-readable program instruction from the network, and transfer the computer-readable program instruction to store it in the computer-readable storage medium provided in the computer device or processing device.

The computer-readable program instruction for executing the operation of the present disclosure may include a machine language instruction and/or a microcode. The machine language instruction and/or the microcode may be compiled or translated from a source code written in a combination of one or more program languages, including an assembly language, Basic, Fortran, Java®, Python, R, C, C++, C #, or similar program languages. All of the computer-readable program instructions may be executed on a user's personal computer, notebook computer, tablet, or smartphone, or may be executed on a remote computer or computer server, or may be executed on a combination of these computer devices. The remote computer or computer server may be connected to a user's device or multiple devices through a computer network such as a local area network, a wide area network, or a global network (Internet). According to some embodiments, in order to implement the aspect of the present disclosure, an electronic circuit including a programmable logic circuit, a field programmable gate array (FPGA), or a programmable logic array (PLA) may execute the computer-readable program instruction to configure or customize the electronic circuit using information from the computer-readable program instruction.

The aspect of the present disclosure will be described with reference to the flowchart and block diagram of a method, device (system), and computer program product according to an embodiment of the present disclosure. Those skilled in the art will understand that each block and combinations of blocks in the flowchart and block diagram may be implemented by the computer-readable program instruction.

The computer-readable program instruction that may implement the system and method described in the present disclosure may be provided to one or more processors (and/or one or more cores in the processor) of a general-purpose computer, a special-purpose computer, or other programmable devices to provide a machine. Thereby, the instruction may be executed through the processor of the computer or other programmable devices to provide a system that performs the functions illustrated in the flowchart and block diagram of the present disclosure. The computer-readable program instruction may be stored in the computer-readable storage medium to function the computer, the programmable device, or other devices in a particular manner so that the computer-readable storage medium having the instruction stored therein is a manufactured article including the instruction for implementing the functional aspect illustrated in the flowchart and block diagram of the present disclosure.

The computer-readable program instruction may be read into the computer, other programmable devices, or other devices to cause the computer, other programmable devices, or other devices to execute a series of operation steps, thus providing a computer implemented program. As a result, the instruction executed by the computer, other programmable devices, or other devices may execute the function illustrated in the flowchart and block diagram of the present disclosure.

FIG. 1 is a functional block diagram illustrating a network system 800 including one or more network computers and servers. In an embodiment, hardware and software environments shown in FIG. 1 may provide an exemplary platform for implementing software and/or method of the present disclosure.

Referring to FIG. 1, the network system 800 may include a computer 805, a network 810, a remote computer 815, a web server 820, a cloud storage server 825, and a computer server 830, but the present disclosure is not limited thereto. In some embodiments, multiple examples of one or more functional blocks shown in FIG. 1 may be used.

FIG. 1 shows further details of the computer 805. The functional blocks in the computer 805 are provided to establish exemplary functions and are not intended to be exhaustive. Although the remote computer 815, the web server 820, the cloud storage server 825, and the computer server 830 are not shown in detail, these other computers and devices may include functions similar to that of the computer 805.

The computer 805 may be a personal computer (PC), a desktop computer, a notebook computer, a tablet computer, a netbook computer, a personal digital assistant (PDA), a smartphone, or other programmable electronic devices capable of communicating with other devices over the network 810.

The computer 805 may include a processor 835, a bus 837, a memory 840, a non-volatile storage 845, a network interface 850, a peripheral interface 855, and a display interface 865. Each of these functions may be implemented as an independent electronic subsystem (an integrated circuit chip or a combination of a chip and an associated device) in some embodiments. In other embodiments, a combination of functions may be implemented on a single chip (sometimes referred to as a system on chip (SoC)).

The processor 835 may be one or more single-chip or multi-chip microprocessors designed and/or manufactured by Intel Corporation, Advanced Micro Devices (Inc.) (AMD), Arm Holdings, Apple computer etc. Examples of the microprocessors may include Celeron, Pentium®, Core i3, Core i5, and Core i7 by Intel Corporation, Opteron, Phenom, Athlon, Turion, and Ryzen by AMD, and Cortex-A, Cortex-R, and Cortex-M by ARM.

The bus 837 may be a proprietary or industry standard high speed parallel or serial interconnect bus, such as ISA, PCI, PCI Express (PCI-e), or AGP.

The memory 840 and the non-volatile storage 845 may be the computer-readable storage medium. The memory 840 may include an appropriate volatile storage device such as a dynamic random access memory (DRAM), a static random access memory (SRAM), etc. The non-volatile storage 845 may include one or more among the flexible disk, the hard disk, the solid state drivee (SSD), the read-only memory (ROM), the erasable programmable read-only memory (EPROM or flash), the compact disk (CD or CD-ROM), the digital versatile disk (DVD), and the memory card or memory stick.

A program 848 may be a combination of machine-readable instruction and/or data, be stored in the non-volatile storage 845, and be used to write, manage, and control the software function described and illustrated in further detail in the present disclosure. In some embodiments, the memory 840 may be significantly faster than the non-volatile storage 845. In the embodiments, the program 848 may be transmitted from the non-volatile storage 845 to the memory 840 prior to execution by the processor 835.

The computer 805 may communicate and interact with another computer via the network 810 through the network interface 850. The network 810 may be, for example, a local area network (LAN), a wide area network (WAN) such as Internet, or a combination thereof, and may include wired, wireless, or optical fiber connection. Generally, the network 810 may be any combination of connections or protocols that support communication between two or more computers or associated devices.

The peripheral interface 855 may allow data input/output into and from other devices that are locally connected to the computer 805. The peripheral interface 855 may be connected to the external device 860, for example. The external device 860 may include devices such as a keyboard, a mouse, a keypad, a touch screen, and/or other suitable input devices. The external device 860 may also include a portable computer-readable storage medium such as a thumb drive, a portable optical disk, a portable magnetic disk, and a memory card. Software and data used to execute the embodiment of the present disclosure, such as the program 848, may be stored in the portable computer-readable storage medium. In such an embodiment, the software may be read into the non-volatile storage 845 or be directly read into the memory 840 via the peripheral interface 855. The peripheral interface 855 may be connected to the external device 860 using an industry standard connection such as RS-232 or Universal Serial Bus (USB).

The display interface 865 may connect the computer 805 to the display 870. In some embodiments, the display 870 may be used to present a command line or graphical user interface to a user of the computer 805. The display interface 865 may be connected to the display 870 using one or more proprietary or industry standard connection such as VGA, DVI, Display Port, and HDMI®.

As described above, the network interface 850 provides communication with other computer systems/devices and storage systems/devices that are provided outside the computer 805. The software program and data described herein may be downloaded from the remote computer 815, the web server 820, the cloud storage server 825, and the computer server 830 through the network interface 850 and the network 810 into the non-volatile storage 845. Further, the system and method described in the present disclosure may be executed by one or more computers connected to the computer 805 via the network interface 850 and the network 810. For example, in some embodiments, the system and method of the present disclosure may be executed by the remote computer 815 on the network 810, the computer server 830, or a combination of interconnected computers.

The data, dataset, and/or database used in the embodiment of the system and method described in the present disclosure may be stored in or downloaded from the remote computer 815, the web server 820, the cloud storage server 825, and the computer server 830.

The circuit used herein may be defined as one or more among an electronic component (e.g. semiconductor device), a plurality of components connected directly to each other or interconnected by electronic communication, the computer, the network of the computer device, the remote computer, the web server, the cloud storage server, and the computer server. For example, one or more of the computer, the remote computer, the web server, the cloud storage server, and the computer server may be included in the circuit or may include the circuit as a component thereof. In some embodiments, multiple examples of one or more of the plurality of components may be used. In this case, each of the multiple examples of one or more components may be included in the circuit or may include the circuit. In some embodiments, a circuit represented by the network system may include a serverless computer system corresponding to a virtual set of multiple hardware resources. A circuit represented by the computer may include a personal computer (PC), a desktop computer, a notebook computer, a tablet computer, a netbook computer, a personal digital assistant (PDA), a smartphone, and other programmable devices that may communicate with other devices over the network. The circuit may be a general-purpose computer, a special-purpose computer, or other programmable devices having one or more processors described herein. Each processor may be one or more single-chip or multi-chip microprocessors. Since the processor has a transistor or other circuits, the processor is considered as a processing circuit or a circuit. The circuit may implement the system and method of the present disclosure on the basis of the computer-readable program instruction that is provided to provide the machine in one or more processors (and/or one or more cores in the processor) of one or more general-purpose computers, special-purpose computers, or other programmable devices described herein. This enables the instruction to be executed by one or more processors of the programmable device included in the circuit or including the circuit, thus providing the system for implementing the function identified in the flowchart and block diagram of the present disclosure. Alternatively, the circuit may be a pre-programmed configuration such as a programmable logic device or a dedicated integrated circuit, or is considered as a circuit regardless of whether it is used alone or in combination with other programmable or pre-programmed circuits.

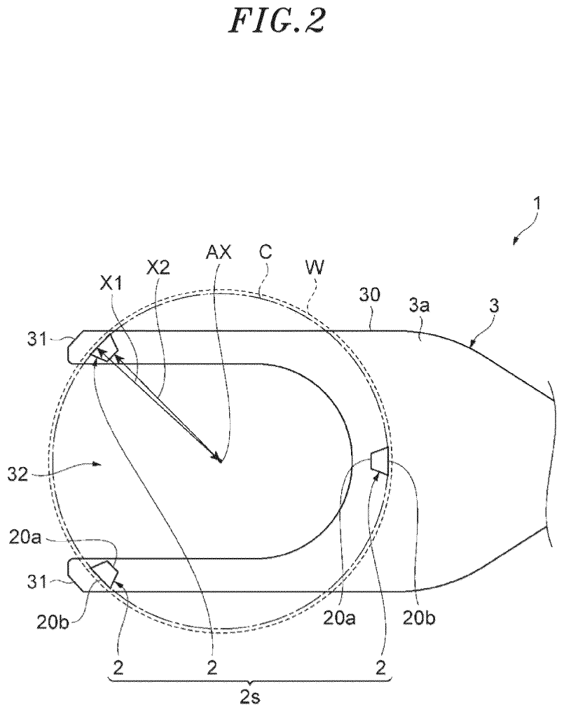

FIG. 2 is a plan view of an end effector according to an exemplary embodiment. The end effector 1 is used in a substrate transfer device. The substrate transfer device includes a substrate transfer robot, for example. The end effector 1 may be used in the transfer arm of the substrate transfer robot. The end effector 1 is also referred to as a transfer pork or a transfer pick.

The end effector 1 includes a blade 3 and a plurality of pads 2s. In an example, the blade 3 includes a main body portion 30 and a pair of tip portions 31. Each of the pair of tip portions 31 protrudes from the main body portion 30. A gap 32 is formed between the pair of tip portions 31. The blade 3 may have a horseshoe shape when seen from a direction in which the substrate W is mounted. The blade 3 is formed of a metal material such as aluminum, titanium, or stainless steel.

In an example, the number of the plurality of pads 2s is three, but may be more than three. In the example of FIG. 1, the plurality of pads 2s are attached to the main body portion 30 and the pair of tip portions 31. The plurality of pads 2s are attached to the blade 3 to support a substrate W on an upper surface 3a of the blade 3. At least one of the plurality of pads 2s is a pad according to one exemplary embodiment. In an embodiment, each of the plurality of pads 2s may be the pad 2. The pad 2 supports the substrate W mounted thereon. The substrate W may have a disk shape.

In an embodiment, the plurality of pads 2s may be arranged along the circumferential direction around a center AX having equal distances from the plurality of pads 2s. In the example of FIG. 2, the center AX is located in the gap 32. The plurality of pads 2s are arranged to surround the gap 32. Further, the plurality of pads 2s may be arranged at equal intervals along the circumferential direction.

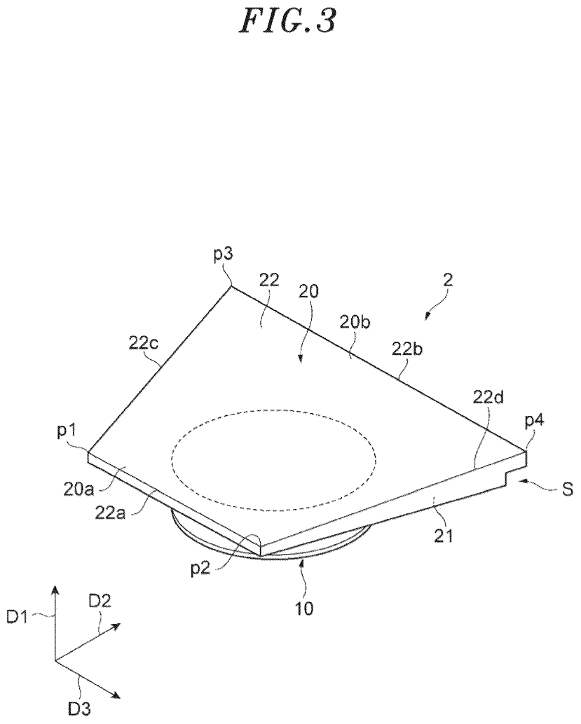

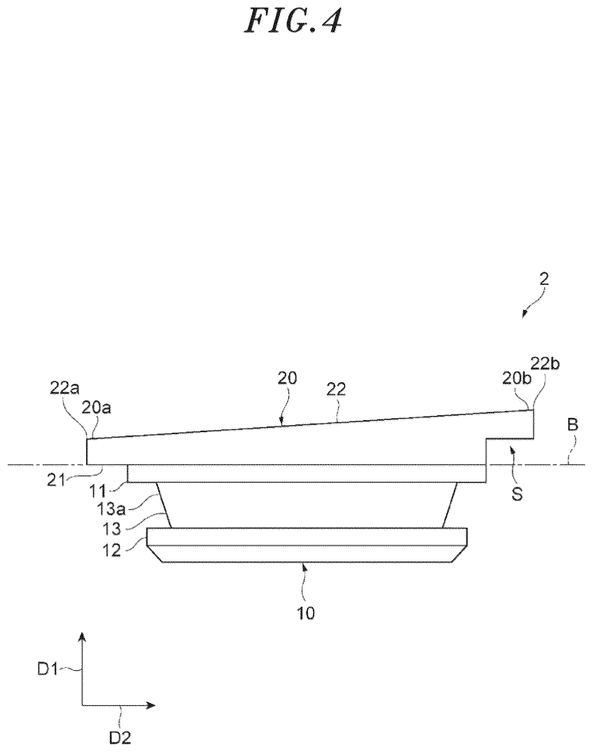

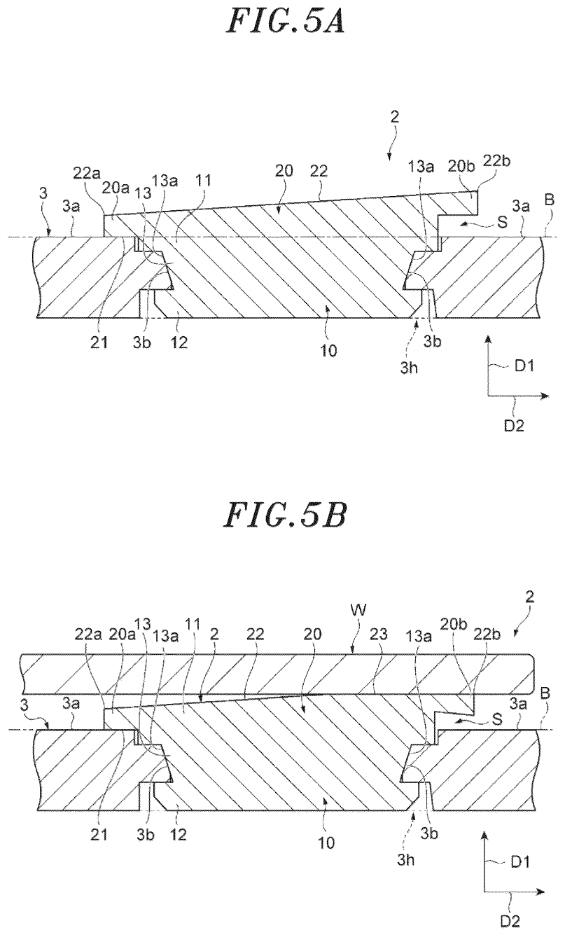

Hereinafter, the pad 2 according to one exemplary embodiment will be described with reference to FIGS. 3 to 5B. FIG. 3 is a perspective view of the pad according to an exemplary embodiment. FIG. 4 is a side view of the pad according to an exemplary embodiment. FIGS. 5A and 5B are partially enlarged sectional views of the end effector according to an exemplary embodiment.

The pad 2 is a pad for the end effector 1 of the substrate transfer device. The pad 2 includes a base portion 10 and a main portion 20. The base portion 10 is a portion held by the blade 3. The main portion 20 (or mounting portion) is a portion that supports the substrate W mounted thereon. As shown in FIG. 4, the main portion 20 is continuous with the base portion 10 in a first direction D1. The first direction D1 of the pad 2 attached to the blade 3 may be the normal direction of the upper surface 3a of the blade 3, or may be aligned with a vertical direction. Hereinafter, the first direction D1 may be referred to as upward, while a direction opposite to the first direction D1 may be referred to as downward.

In an embodiment, the base portion 10 includes a first portion 11, a second portion 12, and a third portion 13. The first portion 11 forms the top of the base portion 10. The first portion 11 is continuous with the main portion 20 in the first direction. In an example, the first portion 11 has a disc shape when seen from the first direction D1. The second portion 12 forms the bottom of the base portion 10. The third portion 13 connects the first portion 11 and the second portion 12 to each other. The first portion 11, the third portion 13, and the second portion 12 are continuous in the first direction. The third portion 13 has a tapered surface 13a whose diameter is reduced downward. The tapered surface 13a is continuous with the lower surface of the first portion 11 and the upper surface of the second portion 12. The minimum diameter of the third portion 13 is smaller than the minimum diameter of the second portion 12. In this way, the base portion 10 may be partially reduced in diameter. The base portion 10 is formed of an elastomer, for example.

The pad 2 may be attached to the blade 3 with the base portion 10 fitted into a through hole 3h of the blade 3. In an example shown in FIG. 5A, the first portion 11 and the third portion 13 are fitted into the through hole 3h, and the second portion 12 functions as a retainer for the through hole 3h. The third portion 13 is fitted into the through hole 3h by fitting a protrusion including a tapered surface 3b defining the through hole 3h into a groove formed by the tapered surface 13a of the third portion 13. The minimum diameter of the second portion 12 is larger than the minimum diameter (i.e., the minimum diameter of the protrusion) of the through hole 3h. The second portion 12 functions as a retainer by returning from a reduced state after passing through the through hole 3h in a radially reduced state.

The main portion 20 includes a lower surface 21, an upper surface 22, a first end 20a, and a second end 20b. The lower surface 21 forms the downward facing surface of the main portion 20. The lower surface 21 may extend from the base portion 10 in a direction intersecting the first direction D1. As shown in the example of FIG. 3, the lower surface 21 may extend from the base portion 10 in a second direction D2 and a third direction D3. The second direction D2 is a direction perpendicular to the first direction D1. The third direction D3 is a direction perpendicular to each of the first direction D1 and the second direction D2. The lower surface 21 is a surface contacting the upper surface 3a of the blade 3. The lower surface 21 is a part of a reference surface B, which will be described later. That is, the reference surface B is a flat virtual plane extending in a direction intersecting or perpendicular to the first direction D1, and includes the lower surface 21.

The upper surface 22 forms the upwardly facing surface of the main portion 20. The upper surface 22 is a surface opposite to the lower surface 21 in the first direction D1. The main portion 20 has elasticity. In an embodiment, the main portion 20 is formed of an elastomer.

As shown in FIG. 4, the first end 20a is one end of the main portion 20 in the second direction D2. The first end 20a may terminate the main portion 20 and the pad 2 in the second direction D2. The second end 20b is the other end of the main portion 20 in the second direction D2. The second end 20b terminates the main portion 20 and the pad 2 in the second direction D2.

As shown in FIG. 5A, in the main portion 20, a distance between the reference surface B and the upper surface 22 increases from the first end 20a to the second end 20b. In other words, a height of the upper surface 22 with respect to the reference surface B increases from the first end 20a to the second end 20b. The distance between the reference surface B and the upper surface 22 may continuously increase from the first end 20a to the second end 20b. When the distance between the reference surface B and the upper surface 22 increases continuously, the upper surface 22 does not include a step. The upper surface 22 has a maximum height with respect to the reference surface B at the second end 20b. In other words, the distance between the reference surface B and the upper surface 22 is maximum at the second end 20b. The upper surface 22 may have a minimum height with respect to the reference surface B at the first end 20a. In other words, the distance between the reference surface B and the upper surface 22 may be minimum at the first end 20a.

In an embodiment, the upper surface 22 may be a flat surface. As shown in FIG. 5A, the upper surface 22 is a flat surface that is inclined with respect to the reference surface B. In an embodiment, an angle between the upper surface 22 and the reference surface B may be 5 degrees or more and 35 degrees or less.

The main portion 20 forms a space S below the second end 20b. The minimum height of the second end 20b with respect to the reference surface B is greater than zero. The space S is formed between the second end 20b and the reference surface B. When the pad 2 is attached to the blade 3, the space S is provided between the second end 20b and the upper surface 3a.

When the substrate W is mounted on the pad 2, the substrate W contacts the second end 20b having the maximum height with respect to the reference surface B. That is, the second end 20b provides a contact region 23 with which the substrate W comes into contact. Therefore, when the substrate W is mounted on the pad 2, the load of the substrate W is applied to the second end 20b. The second end 20b is a terminal end in the second direction D2, and forms the space S below, as described above. Therefore, as shown in FIG. 5B, the second end 20b to which the load from the substrate W is applied is easily subjected to elastic deformation toward the space S below. Due to the elastic deformation of the second end 20b, a contact area between the substrate W and the pad 2 increases. Therefore, the positional misalignment of the substrate W is suppressed by the pad 2.

Further, as described above, the height of the upper surface 22 with respect to the reference surface B continuously increases toward the second end 20b. Therefore, even when the substrate W curved to bulge downward is mounted on the pad, the substrate W reliably contacts the second end 20b.

Further, the main portion 20 may be elastically deformed so that the second end 20b may be tilted downward. Therefore, the pad 2 on which the substrate W is mounted is elastically deformed by the load of the substrate W so that the second end 20b is tilted downward. When the substrate W is lifted in a state where the main portion 20 is elastically deformed so that the second end 20b is tilted downward, a restoring force for moving the second end 20b upward is applied to the substrate W from the main portion 20. Therefore, when lifting the substrate W from the pad 2, the substrate W may be easily detached from the pad 2. Therefore, when lifting the substrate W from the pad 2, bouncing of the substrate W is suppressed.

In an embodiment, the edge of the upper surface 22 may include a plurality of vertices. The edge of the upper surface 22 at the second end 20b may be composed of a line segment or an outwardly bulging arc. That is, the shape of the upper surface 22 may be a polygon, or a part of the edge of the upper surface 22 may include an arc.

In the example shown in FIG. 3, as an example, the edge of the upper surface 22 includes a plurality of vertices p1, p2, p3, and p4. The vertices p1 and p2 are adjacent to each other along the third direction D3 at the edge of the upper surface 22. The vertices p3 and p4 are adjacent to each other along the third direction D3 at the edge of the upper surface 22. The vertices p1 and p3 are adjacent to each other along the second direction D2 at the edge of the upper surface 22. The vertices p2 and p4 are adjacent to each other along the second direction D2 at the edge of the upper surface 22.

The edge of the upper surface 22 at the first end 20a may be formed of an arc that bulges toward the inside of the upper surface 22. One end of the arc 22a in the third direction D3 forms the vertex p1, while the other end of the arc 22a in the third direction D3 forms the vertex p2. Further, the edge of the upper surface 22 at the first end 20a may be formed of a line segment. The edge of the upper surface 22 at the second end 20b may be formed of an arc 22b that bulges toward the outside of the upper surface 22. One end of the arc 22b in the third direction D3 forms the vertex p3, while the other end of the arc 22b in the third direction D3 forms the vertex p4. Further, the edge of the upper surface 22 at the second end 20b may be formed of a line segment. One edge of the upper surface 22 in the third direction D3 is formed of a line segment 22c. The line segment 22c extends between the vertices p1 and p3. The other edge of the upper surface 22 in the third direction D3 is formed of a line segment 22d. The line segment 22d extends between the vertices p2 and p4.

In an embodiment, a distance between two vertices adjacent to each other at the edge of the upper surface 22 among the plurality of vertices may be 5 mm or more and 30 mm or less. For example, a distance between the vertices p1 and p2, a distance between the vertices p3 and p4, a distance between the vertices p1 and p3, and a distance between the vertices p2 and p4 each may be 5 mm or more and 30 mm or less.

In an embodiment, the width of the upper surface 22 may be maximum at the second end 20b. The width of the upper surface 22 is, for example, the length of the upper surface 22 along the third direction D3. Further, in the example of FIG. 3, the length of the arc 22b is larger than the length of the arc 22a. Therefore, since a large contact area between the substrate W and the pad 2 is ensured due to the pad 2, the positional misalignment of the substrate W is suppressed.

Turning back to FIG. 2, the end effector 1 according to an exemplary embodiment will be described.

In an embodiment, each of the plurality of pads 2s may be disposed in the end effector 1 such that a distance X2 between the second end 20b and the center AX is larger than a distance X1 between the first end 20a and the center AX.

In an embodiment, the edge of the upper surface 22 of each of the plurality of pads 2s may be formed, at the second end 20b, of an arc forming a part of a circle C having the center AX or a line segment tangent to the circle. In the example of FIG. 2, the arc 22b forming the edge of the upper surface 22 at the second end 20b is formed of an arc forming a part of the circle C.

In an embodiment, the diameter of the largest circle having the center AX and circumscribing the main portion 20 of each of the plurality of pads 2 may be smaller than the diameter of the substrate W. In an example of FIG. 2, the circle C forms the largest circle circumscribing the main portion 20 of each of the plurality of pads 2s. The diameter of the circle C is smaller than the diameter of the substrate W.

In the end effector 1, the reaction force exerted on the substrate W by the second end 20b of each of the plurality of pads 2s includes a component directed toward the center AX. Therefore, according to the end effector 1, the positional misalignment of the substrate W is suppressed by one end effector in a radial direction with respect to the center AX.

Although various exemplary embodiments have been described above, various additions, omissions, substitutions, and changes may be made without being limited to the exemplary embodiments described above. In addition, elements of different embodiments may be combined to form other embodiments.

For example, when the edge of the upper surface 22 at the first end 20a and the edge of the upper surface 22 at the second end 20b each are formed of a line segment, the upper surface 22 may have a trapezoidal shape when seen from the first direction D1.

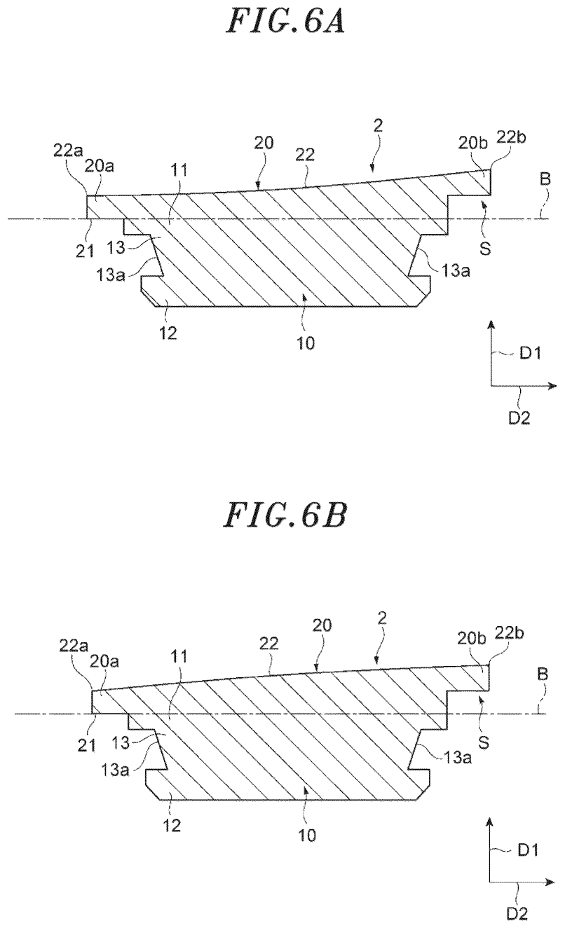

FIG. 6A is a sectional view of a pad according to another exemplary embodiment. As shown in FIG. 6A, the upper surface 22 may be concave. FIG. 6B is a sectional view of a pad according to a further exemplary embodiment. As shown in FIG. 6B, the upper surface 22 may be convex.

Various exemplary embodiments included in the present disclosure are described in [E1] to [E15] below.
[E1]

A pad for an end effector of a substrate transfer device, the pad comprising:
a base portion; and
a main portion in continuity with the base portion in a first direction,
wherein the main portion comprises:
a lower surface extending from the base portion in a direction intersecting the first direction;
a first end that is one end of the main portion in a second direction perpendicular to the first direction;
a second end that is the other end of the main portion in the second direction and terminates the main portion and the pad in the second direction; and
an upper surface,
wherein a distance between a reference surface including the lower surface and the upper surface increases from the first end to the second end, and
the upper surface has a maximum height at the second end with respect to the reference surface, and the main portion has elasticity and forms a space below the second end.
[E2]

The pad of E1, wherein the upper surface provides a contact region at the second end to contact a substrate.
[E3]

The pad of E1 or E2, wherein the main portion is elastically deformable such that the second end is tiltable.
[E4]

The pad of any one of E1 to E3, wherein the upper surface is a flat surface or a concave surface.
[E5]

The pad of any one of E1 to E4, wherein an angle between the upper surface and the reference surface is 5 degrees or more and 35 degrees or less.
[E6]

The pad of any one of E1 to E5, wherein an edge of the upper surface comprises a plurality of vertices, and
the edge of the upper surface at the second end is formed of a line segment or an outwardly bulging arc.
[E7]

The pad of E6, wherein a distance between any two vertices adjacent to each other at the edge of the upper surface among the plurality of vertices is 5 mm or more and 30 mm or less.
[E8]

The pad of any one of E1 to E7, wherein the main portion is formed of an elastomer.
[E9]

The pad of any one of E1 to E8, wherein a width of the upper surface is maximum at the second end.
[E10]

An end effector comprising:
a blade; and
a plurality of pads attached to the blade to support a substrate on the blade,
wherein at least one of the plurality of pads is a pad according to any one of E1 to E9.
[E11]

The end effector of E10, wherein the plurality of pads are arranged along a circumferential direction around a center having the same distance from the plurality of pads.
[E12]

The end effector of E10 or E11, wherein each of the plurality of pads is the pad according to any one of E1 to E9.
[E13]

The end effector of E12, wherein each of the plurality of pads is disposed such that a distance between the second end and the center is larger than a distance between the first end and the center.
[E14]

The end effector of E12 or E13, wherein an edge of the upper surface of each of the plurality of pads is formed, at the second end, of an arc forming a part of a circle having the center or a line segment tangent to the circle.
[E15]

The end effector of any one of E12 to E14, wherein a diameter of a largest circle having the center and circumscribing the main portion of each of the plurality of pads is smaller than a diameter of the substrate.

From the foregoing description, it should be understood that various embodiments of the present disclosure have been described herein for purposes of illustration and that various changes may be made without departing from the scope and spirit of the present disclosure. Therefore, the embodiments disclosed herein are not intended to limit the technology of the present disclosure, and the scope of the present disclosure should be determined based on the following claims.

1. A pad for an end effector of a substrate transfer device, the pad comprising:
a base portion; and
a main portion in continuity with the base portion in a first direction,
wherein the main portion comprises:
a lower surface extending from the base portion in a direction intersecting the first direction;
a first end that is one end of the main portion in a second direction perpendicular to the first direction;
a second end that is the other end of the main portion in the second direction and terminates the main portion and the pad in the second direction; and
an upper surface,
wherein a distance between a reference surface including the lower surface and the upper surface increases from the first end to the second end, and
the upper surface has a maximum height at the second end with respect to the reference surface, and the main portion has elasticity and forms a space below the second end.

2. The pad of claim 1, wherein the upper surface provides a contact region at the second end to contact a substrate.

3. The pad of claim 1, wherein the main portion is elastically deformable such that the second end is tiltable.

4. The pad of claim 1, wherein the upper surface is a flat surface or a concave surface.

5. The pad of claim 4, wherein an angle between the upper surface and the reference surface is 5 degrees or more and 35 degrees or less.

6. The pad of claim 1, wherein an edge of the upper surface comprises a plurality of vertices, and
the edge of the upper surface at the second end is formed of a line segment or an outwardly bulging arc.

7. The pad of claim 6, wherein a distance between any two vertices adjacent to each other at the edge of the upper surface among the plurality of vertices is 5 mm or more and 30 mm or less.

8. The pad of claim 1, wherein the main portion is formed of an elastomer.

9. The pad of claim 1, wherein a width of the upper surface is maximum at the second end.

10. An end effector comprising:
a blade; and
a plurality of pads attached to the blade to support a substrate on the blade,
wherein at least one of the plurality of pads is a pad according to claim 1.

11. The end effector of claim 10, wherein the plurality of pads are arranged along a circumferential direction around a center having the same distance from the plurality of pads.

12. The end effector of claim 11, wherein each of the plurality of pads respectively comprising
a base portion; and
a main portion in continuity with the base portion in a first direction,
wherein the main portion comprises:
a lower surface extending from the base portion in a direction intersecting the first direction;
a first end that is one end of the main portion in a second direction perpendicular to the first direction;
a second end that is the other end of the main portion in the second direction and terminates the main portion and the pad in the second direction; and
an upper surface,
wherein a distance between a reference surface including the lower surface and the upper surface increases from the first end to the second end, and
the upper surface has a maximum height at the second end with respect to the reference surface, and the main portion has elasticity and forms a space below the second end.

13. The end effector of claim 12, wherein each of the plurality of pads is disposed such that a distance between the second end and the center is larger than a distance between the first end and the center.

14. The end effector of claim 13, wherein an edge of the upper surface of each of the plurality of pads is formed, at the second end, of an arc forming a part of a circle having the center or a line segment tangent to the circle.

15. The end effector of claim 13, wherein a diameter of a largest circle having the center and circumscribing the main portion of each of the plurality of pads is smaller than a diameter of the substrate.
